(19) United States
(12) Patent Application Publication
(10) Pub. No.: US 2013/0237044 A1
(43) Pub. Date: Sep. 12, 2013

(54) METHOD OF MANUFACTURING METAL GATES

(71) Applicants: Hsiao-chia CHEN, Taichung City (TW); Chien-hua TSAI, Taichung City (TW)

(72) Inventors: Hsiao-chia CHEN, Taichung City (TW); Chien-hua TSAI, Taichung City (TW)

(21) Appl. No.: 13/416,380

(22) Filed: Mar. 9, 2012

(51) Int. Cl. H01L 21/283

(52) U.S. Cl. 438/587; 257/E21.19

(57) ABSTRACT

A method of manufacturing metal gates comprises the steps of: forming a plurality of parallel trenches on a substrate; forming sequentially a conductive layer and a protective layer on the surfaces of the substrate and trenches; removing the protective layer and conductive layer on the surface of the substrate and the protective layer on the bottom walls of the trenches through anisotropic etching to retain only the protective layer and conductive layer on the side walls; and finally removing the conductive layer not covered by the protective layer through isotropic etching to retain only the protective layer and conductive layer on the side walls so that two insulating gates are respectively formed on the side walls. Thus no isolation material is needed to be disposed at the bottom of the trenches, and the problem of excessive etching to the trenches that results in undesirable insulation can be averted.

### FIELD OF THE INVENTION

The present invention relates to a metal gate and particularly to a method of manufacturing metal gates.

### BACKGROUND OF THE INVENTION

Constant advances of semiconductor manufacturing technology have greatly shrunken the size of electronic elements while greatly improve their performances. Research and development of semiconductor manufacturing process mainly focus on shrinking the size of transistors to increase circuit density of elements so that element size can be reduced to improve switching speed and power consumption, thereby to enhance the functionality of the elements. Shrinking the element size must be incorporated with precisely controlled etching process and equipments to make improving production yield possible.

Please refer to FIG. 1A, in a conventional process for manufacturing transistors that are arranged in an array, such as Dynamic Random Access Memory (DRAM), a trench 1 and pillars 2 relative to the trench 1 are formed by digging, and a conductor 3 is deposited in the trench 1. As shown in FIG. 1C, the conductor 3 is separated to form gates 4 attached to the surfaces of the pillars 2. But, as shown in FIG. 1B, during forming the trench 1 its bottom 5 could form a sub trench 6 due to uneven etching direction and speed. As a result, when the conductor 3 is deposited, it also fills the sub trench 6 at the same time as shown in FIG. 1C. When the conductor 3 is separated, the gates 4 at two sides are still connected to each other since the conductor 3 in the sub trench 6 is not fully etched away. Therefore the etching process has to be continued to remove the conductor 3 in the sub trench 6 as shown in FIG. 1D. This makes the gates 4 thinner and easily peeling off, being damaged or lacking sufficient conductivity. Moreover, if the bottom 5 of the trench 1 is excessively etched, it could become too thin to result in the risk of electric leakage.

To resolve the aforesaid problem, another conventional technique for forming the gate was developed. It first forms an isolation layer on the bottom surface of the trench, and then forms the conductor in the trench. As the isolation layer has filled the sub trench, the conductor is formed flatly on the isolation layer, and then the process of separating the conductor by etching can be performed smoothly. Moreover, the isolation layer also functions as a barrier so that etching solution or gas cannot etch the trench downwards continuously, therefore the bottom of the trench is free from the excessive etching problem.

Please also refer to FIGS. 2, 3A and 3B for a conventional technique to form matrix transistors. First, a structure including a trench 1, pillars 2 and insulators 8 interposed among the pillars 2 is formed; next, oxide material is formed in the trench 1; finally, a deep etching process is performed to etch the oxide material to a desired thickness to form an isolation layer 7 as shown in FIGS. 3A and 3B. Due to the pillars 2 are made from silicon, they are not affected very much during etching of the isolation layer 7. But as shown in FIG. 3B, the isolators 8 and isolation layer 7 are made of oxide, substantially same type of material; during etching of the isolation layer 7 the isolators 8 also are etched to become thinner. When the conductor 3 is deposited an uneven structure is formed as shown in FIG. 4. The thinner insulators 8 could also result in poor insulation. Moreover, because of the thinner insulators 8, they form uneven surface with the pillars 2, thus incomplete deposition of the conductor 3 could happen.

In addition, the depositing material used for the isolation layer 7 could oxidize the pillars 2 to reduce the thickness thereof. During the deep etching process, a portion of the pillars 2 also is etched away. It is also difficult to control the thickness of the pillars 2 via oxidation, and prevent excessively etching to the pillars 2 during the deep etching process. All this creates a lot of difficulty in precise control of the thickness of the pillars 2.

### SUMMARY OF THE INVENTION

The primary object of the present invention is to provide a method to separate metal gates.

Another object of the invention is to solve the problem of the conventional techniques with the isolation layer disposed on the bottom of the trench that results in excessive etching and undesirable insulation.

To achieve the foregoing objects, the invention provides a method of manufacturing metal gates that comprises the following steps:

S1: forming a substrate with a plurality of parallel trenches each having a bottom wall and two side walls perpendicular to the bottom wall;

S2: forming a conductive layer on the surface of the substrate and the bottom walls and side walls of the trenches;

S3: forming a protective layer on the conductive layer;

S4: removing the protective layer on the surface of the substrate and the bottom walls of the trenches through anisotropic etching to retain the protective layer and conductive layer on the side walls of the trenches; and

S5: removing the conductive layer not covered by the protective layer through isotropic etching to retain only the protective layer and conductive layer on the side walls of the trenches so that two insulating gates are respectively formed on the two side walls of one trench.

In one aspect the conductive layer is selectively made of metal and metal nitride.

In another aspect the protective layer is formed on the surface of the conductive layer through an Atomic Layer Deposition (ACD) technique or a Supercritical Fluid Deposition (SFD) process.

In yet another aspect the conductive layer at step S5 is removed via an isotropic dry etching process.

In yet another aspect the step Si further includes sub-steps as follows:

S1A: forming a plurality of ditches on the substrate in a first direction and filling an insulation material in the ditches; and

S1B: forming the trenches that are spaced from each other on the substrate in a second direction perpendicular to the first direction so that a plurality of pillars and a plurality of insulators are formed on the substrate in a staggered manner relative to the trenches.

In yet another aspect the insulation material at the sub-step S1A is filled in the ditches via a Spin on Dielectric (SOD) process.

In yet another aspect another sub-step S1C is provided for oxidizing the surfaces of the side walls and bottom walls of the trenches via an In Situ Steam Generation (ISSG) technique.

In yet another aspect the protective layer is selectively made of nitride and oxide.

By means of the aforesaid method of the invention, there is no need to dispose isolation material at the bottom of the trenches, hence the problem of excessive etching to the trenches that results in undesirable insulation can be prevented, and another problem of etching the insulators to result in incomplete deposition of the conductive layer in the downstream process also can be averted.

The foregoing, as well as additional objects, features and advantages of the invention will be more readily apparent from the following detailed description, which proceeds with reference to the accompanying drawings.

### BRIEF DESCRIPTION OF THE DRAWINGS

FIGS. 1A through 1D are schematic views of a conventional gate fabricating process.

FIG. 2 is a top view of trenches and pillars according to a conventional technique.

FIG. 3A is a cross section taken on line A-A in FIG. 2.

FIG. 3B is a cross section taken on line B-B in FIG. 2.

FIG. 4 is a top view of trenches and pillars according to another conventional technique.

FIG. 5A is a top view of an embodiment of the invention.

FIG. 5B is another top view of an embodiment of the invention.

FIGS. 6A through 6E are schematic views of manufacturing processes according to an embodiment of the invention.

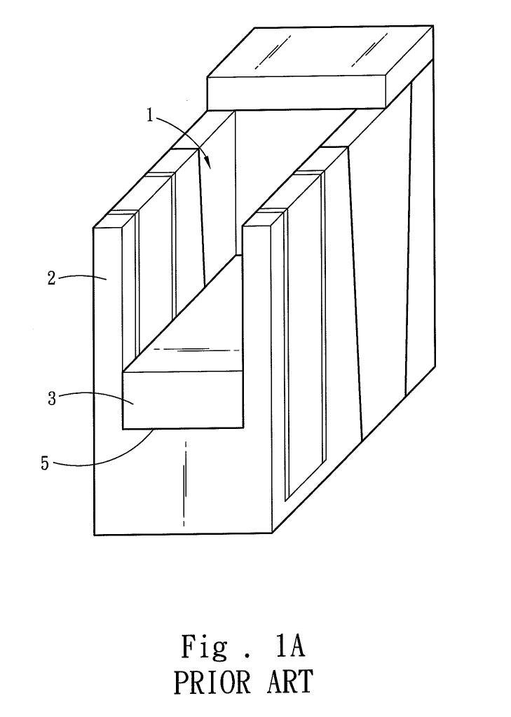

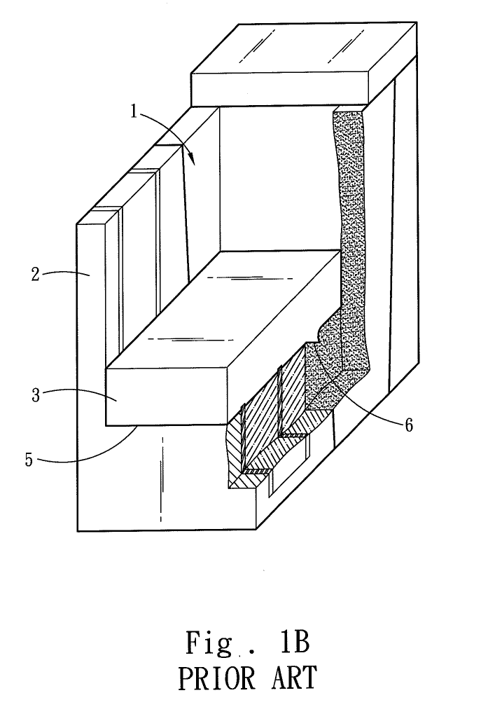

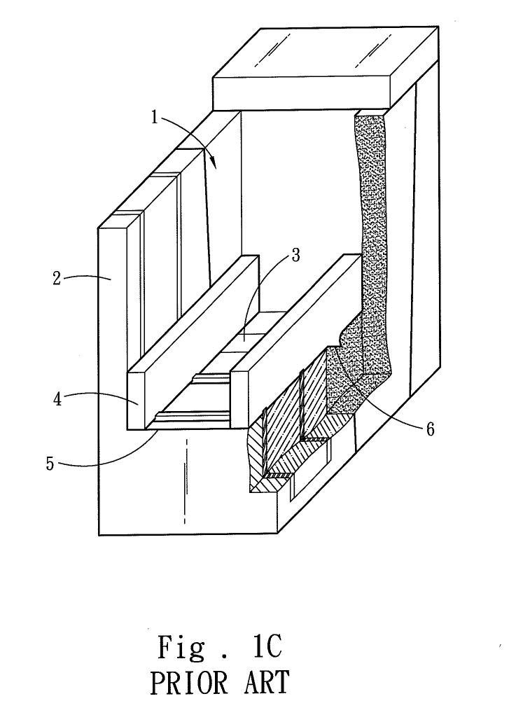

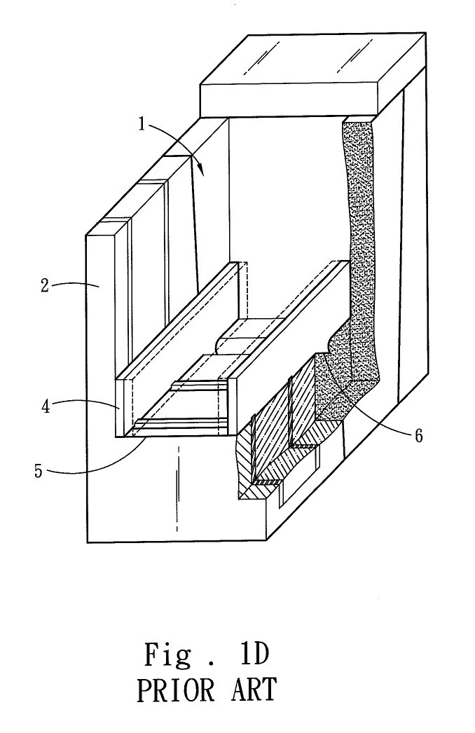

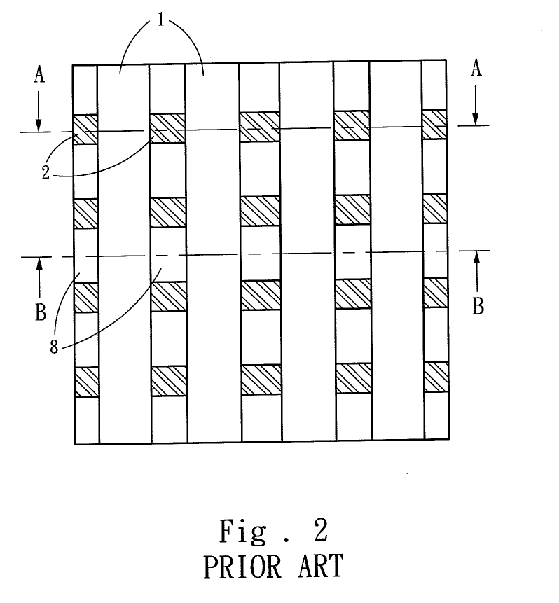

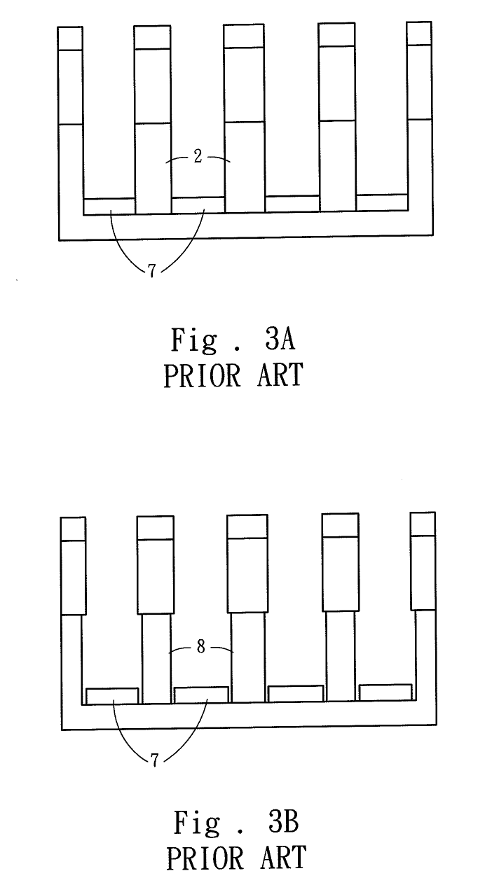

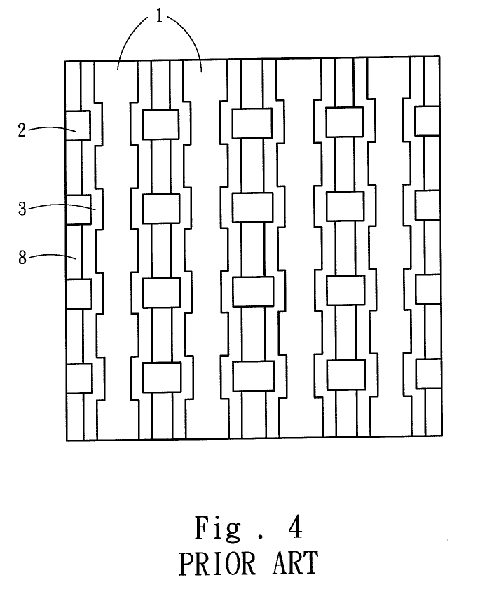

### DETAILED DESCRIPTION OF THE PREFERRED EMBODIMENTS

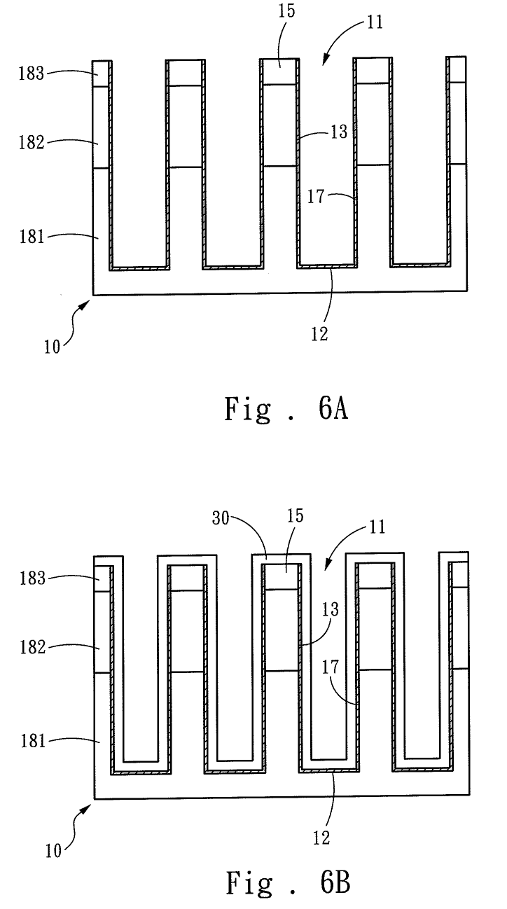

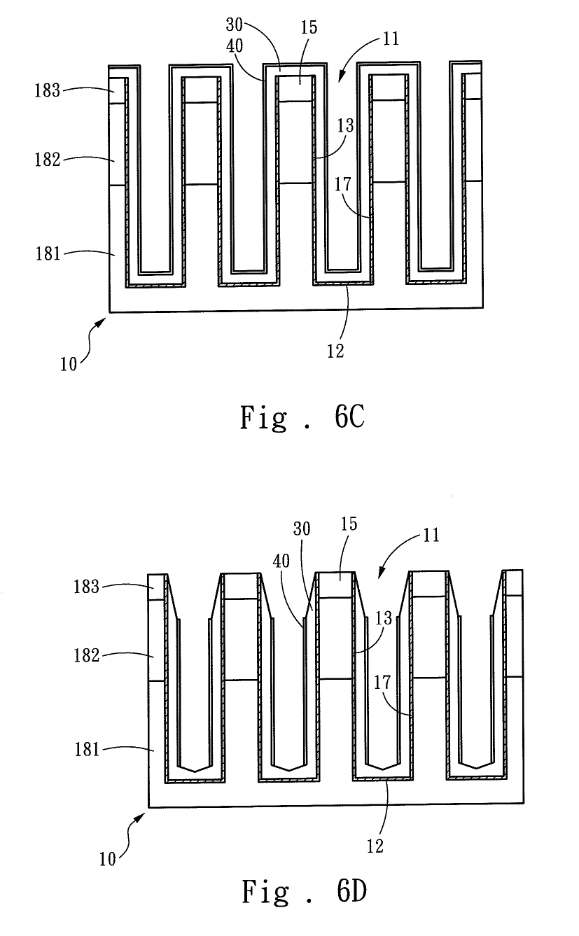

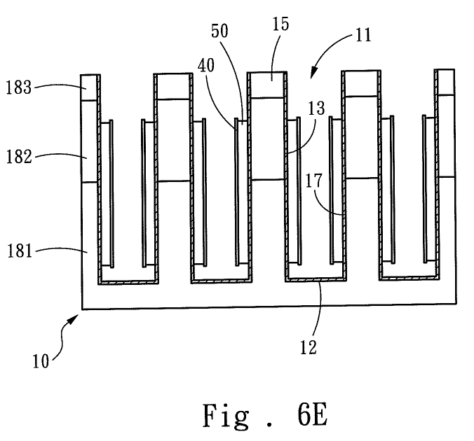

The present invention aims to provide a method for manufacturing metal gates that comprises the steps as follows, also referring to FIG. 6A:

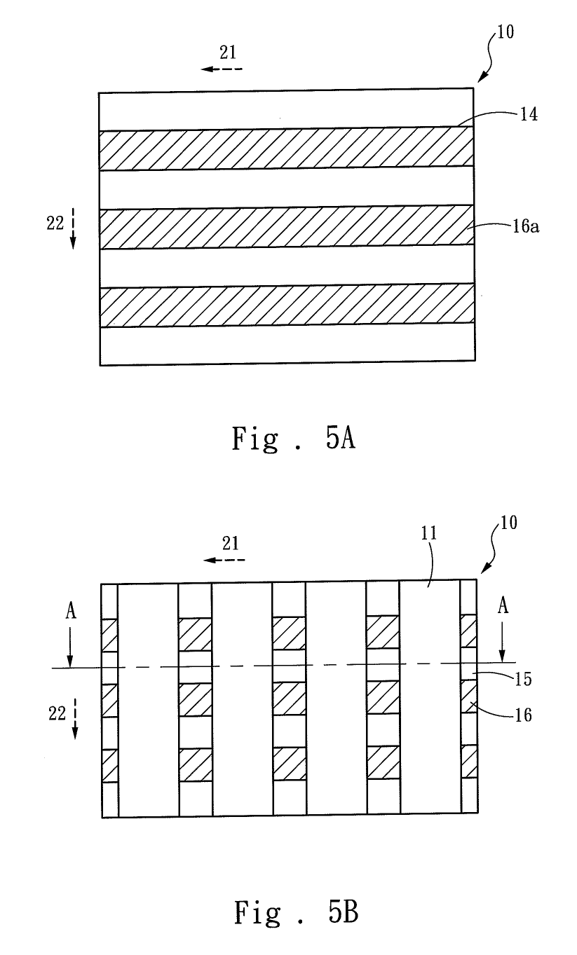

S1: forming a substrate 10 with a plurality of parallel trenches 11 each having a bottom wall 12 and two side walls 12 perpendicular to the bottom wall 12. Take a transistor structure for DRAM as an example, also refer to FIGS. 5A and 5B for an embodiment, the DRAM is an array structure. The step S1 further includes sub-steps as follow:

S1A: forming a plurality of ditches 14 on the substrate 10 in a first direction 21 as shown in FIG. 5A and filling an insulation material 16a in the ditches 14 via a Spin On Dielectric (SOD) process;

S1B: forming the trenches 11 that are spaced from each other on the substrate 10 in a second direction 22 perpendicular to the first direction 21 so that a plurality of pillars 15 and a plurality of insulators 16 are formed on the substrate 10 in a staggered manner relative to the trenches 11 as shown in FIG. 5B. The pillars 15 are doped or ion-planted to form drains, sources and passage layers between the drains and sources; and

S1C: isolating the periphery of the trenches 11, referring to FIG. 6A which is a cross section taken on line A-A in FIG. 5B. In this embodiment, the surfaces of the side walls 13 and bottom walls 12 of the trenches 11 are oxidized via an In Situ Steam Generation (ISSG) process in which the silicon in the trenches 11 is oxidized via oxygen-contained gas to form an oxide layer 17 on the surfaces of the side walls 13 and bottom walls 12. In this embodiment the substrate 10 includes a silicon-based layer 181 at the bottom, a silicon nitride layer 182 for etching to fend off etching material and an elevation adjustment layer 183 at the top end. By controlling the thickness of the elevation adjustment layer 183 the depth of the trench 11 can be adjusted.

S2: forming a conductive layer 30 on the surface of the substrate 10 and the bottom walls 12 and side walls 13 of the trenches 11, referring to FIG. 6B. The conductive layer 30 can be made of metal or metal nitride, such as titanium nitride or the like.

S3: forming a protective layer 40 on the conductive layer 30, referring to FIG. 6C. The protective layer 40 can be made of nitride or oxide, such as silicon oxide, silica, silicon nitride or the like, and formed on the surface of the conductive layer 30 via an Atomic Layer Deposition (ALD) technique or a Supercritical Fluid Deposition (SFD) process.

S4: removing the protective layer 40 on the surface of the substrate 10 and bottom walls 12 of the trenches 11 in the horizontal direction through anisotropic etching to retain the protective layer 40 on the side walls 13, referring to FIG. 6D. To meet this end, an etching material with a high etching selectivity ratio for the protective layer 40 should be selected. In this embodiment, the protective layer 40 and conductive layer 30 can also be etched by an etching material of a lower etching selectivity ratio, and by controlling the etching duration to control etching area and depth, as shown in FIG. 6D. As etching on the protective layer 40 and conductive layer 30 on the bottom walls 12 via the etching material is more difficult, once the protective layer 40 on the bottom walls 12 is removed by etching, the anisotropic etching can be stopped, while a portion of the conductive layer 30 on the bottom walls 12 will also be removed by etching but not penetrating the bottom walls 12. Such an approach can entirely etch the protective layer 40 and conductive layer 30 on the surface of the substrate 10 because they have great contact area with the etching material, while the area at the top of the substrate 10 and trenches 11 is partly etched and removed to retain a portion of the conductive layer 30. The protective layer 40 on the side walls 13 is retained due to the anisotropic etching. Thus the etching material of a lower etching selectivity ratio can be selected to accomplish the anisotropic etching.

S5: removing the conductive layer 30 not covered by the protective layer 40 through isotropic etching, referring to FIG. 6E to retain only the protective layer 40 and conductive layer 30 on the side walls 13 of the trenches 11 so that two insulating gates 50 are respectively formed on the two side walls 13 of one trench 11. In this embodiment, an isotropic dry etching process is selected to reduce the possibility of etching the conductive layer 30 between the protective layer 40 and side walls 13. The invention can also adopt isotropic wet etching process. Due to the isotropic wet etching process can also easily etch the conductive layer 30 between the protective layer 40 and side walls 13, etching duration and speed must be controlled closely. By means of the processes set forth above, the conductive layer 30 can be separated to form the gates 50 respectively on the side walls 13, and by incorporating with the sources, drains and passage layers formed on the pillars 15, a desired transistor structure is thus formed.

As a conclusion, compared with the conventional techniques, the invention provides features as follow:

1. The problem of excessive etching caused by disposing isolation material at the bottom of the trenches that results in undesirable insulation can be avoided.

2. The problem of etching the insulators to result in incomplete deposition of the conductive layer in the downstream process can also be averted.

3. There is no need to dispose an isolation layer on the bottom, thus oxidization of the pillars can be prevented and deep etching to the pillars also can be avoided. Hence the thickness of the pillars can be controlled precisely.

While the preferred embodiment of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention set forth in the claims.

1. A method of manufacturing metal gates, comprising the steps of:
S1: forming a substrate including a plurality of parallel trenches each including a bottom wall and two side walls perpendicular to the bottom wall;
S2: forming a conductive layer on a surface of the substrate and the bottom walls and the side walls of the plurality of trenches;
S3: forming a protective layer on the conductive layer;
S4: removing the protective layer on the surface of the substrate and the bottom walls of the trenches through anisotropic etching, the anisotropic etching only removing the protective layer in the horizontal direction and retaining the protective layer on the side walls, wherein a portion of the conductive layer on the bottom walls will also be removed by etching but not penetrating the bottom walls; and
S5: removing the conductive layer n covered by the protective layer through isotropic etching to separate the conductive layer and to form the gates respectively on the side walls of the trenches.

2. The method of claim 1, wherein the conductive layer is selectively made of metal and metal nitride.

3. The method of claim 1, wherein the protective layer is selectively formed on a surface of the conductive layer through an atomic layer deposition technique and a supercritical fluid deposition process.

4. The method of claim 1, wherein the conductive layer at the step S5 is removed via an isotropic dry etching process.

5. The method of claim 1, wherein the step Si further includes sub-steps of:
S1A: forming a plurality of ditches on the substrate in a first direction and filling an insulation material in the plurality of ditches; and
S1B: forming the trenches that are spaced from each other on the substrate in a. second direction perpendicular to the first direction so that a plurality of pillars and a plurality of insulators are formed on the substrate in a staggered fashion relative to the trenches.

6. The method of claim 5, wherein the insulation material at the sub-step S1A is filled in the ditches via a spin-on dielectric process.

7. The method of claim 5 further including another sub-step S1C for oxidizing surfaces of the side walls and the bottom walls of the trenches via an in situ steam generation process.

8. The method of claim 1, wherein the protective layer is selectively made of nitride and oxide.
